(19) United States
(12) Patent Application Publication
(10) Pub. No.: US 2009/0134437 A1
(43) Pub. Date: May 28, 2009

(54) IMAGE SENSOR AND CMOS IMAGE SENSOR

(75) Inventors: Hayato Nakashima, Anpachi-gun (JP); Ryu Shimizu, Mizuho-shi (JP); Mamoru Arimoto, Ogaki-shi (JP); Kaori Misawa, Kaizu-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/274,918

(22) Filed: Nov. 20, 2008

(30) Foreign Application Priority Data
Nov. 21, 2007 (JP) 2007-301282

(51) Int. Cl. H01L 31/02; H01L 27/00; H01L 27/105

(52) U.S. Cl. 257/292; 250/208.1; 257/E31.113; 257/E27.081

(57) ABSTRACT

In an image sensor, a first electrode, a second electrode, a third electrode and a fourth electrode are formed between a photoelectric conversion portion and a voltage conversion portion and are provided so as not to overlap with at least a part of the photoelectric conversion portion in plan view.

### CROSS-REFERENCE TO RELATED APPLICATIONS

The priority application number JP2007-301282, Image Sensor, Nov. 21, 2007, Hayato Nakashima, Ryu Shimizu, Mamoru Arimoto, Kaori Misawa, upon which this patent application is based is hereby incorporated by reference.

### BACKGROUND OF THE INVENTION

1. Field of the Invention

The present invention relates to an image sensor and a CMOS image sensor, and more particularly, it relates to an image sensor and a CMOS image sensor each comprising a region for increasing the number of signal charges.

2. Description of the Background Art

An image sensor (CMOS image sensor) comprising a region for increasing (multiplying) the number of electrons (signal charges) is known in general.

In a conventional image sensor, five gate electrodes of a first transfer gate electrode for forming a pixel separation barrier on a transfer channel of the electrons, a second transfer gate electrode for temporarily storing the electrons in the transfer channel of the electrons, a third transfer gate electrode forming a barrier when transferring the electrons, a multiplier gate electrode for forming an electric field multiplying the electrons by impact ionization and a readout gate electrode for transferring the electrons stored in a portion under the multiplier gate electrode to read data are arranged from a photodiode toward a floating diffusion region in this order. This conventional image sensor is so formed that the electrons are repeatedly multiplied (increased) between a portion of the transfer channel located under the second transfer gate electrode and a portion of the transfer channel located under the multiplier gate electrode.

In general, there also exists an image sensor where four gate electrodes of a first transfer gate electrode for storing electrons in a photodiode, formed on a surface of the photodiode, a second transfer gate electrode for transferring the electrons stored in the photodiode, a multiplier gate electrode for forming an electric field multiplying the electrons by impact ionization and a readout gate electrode transferring the electrons stored in a portion located under the multiplier gate electrode to read data are arranged from the photodiode toward a floating diffusion region in this order. In this image sensor comprising the four gate electrodes, the electrons are multiplied between the photodiode located under the first transfer gate electrode and the portion of the transfer channel located under the multiplier gate electrode. The number of this image sensor comprising the four gate electrodes is one gate electrode smaller than that of the aforementioned image sensor comprising the five gate electrode. Thus, the area of the photodiode can be increased when the pixel sizes are the same, and hence sensitivity of the photodiode can be improved.

### SUMMARY OF THE INVENTION

An image sensor according to a first aspect of the present invention comprises a first electrode for forming an electric field storing signal charges, a second electrode for forming another electric field increasing the number of the signal charges, a photoelectric conversion portion generating the signal charges, a voltage conversion portion for converting the signal charges to a voltage, a third electrode for transferring the signal charges to the voltage conversion portion, a fourth electrode provided between the first electrode and the second electrode for transferring the signal charges and a transfer channel provided under the first electrode, the second electrode, the third electrode and the fourth electrode for performing a signal charge transferring operation and a signal charge increasing operation, wherein the first electrode, the second electrode, the third electrode and the fourth electrode are formed between the photoelectric conversion portion and the voltage conversion portion and provided so as not to overlap with at least a part of the photoelectric conversion portion in plan view.

A CMOS image sensor according to a second aspect of the present invention comprises a first electrode for forming an electric field storing signal charges, a second electrode for forming another electric field increasing the number of the signal charges, a photoelectric conversion portion generating the signal charges, a voltage conversion portion for converting the signal charges to a voltage, a third electrode for transferring the signal charges to the voltage conversion portion, a fourth electrode provided between the first electrode and the second electrode for transferring the signal charges and a transfer channel provided under the first electrode, the second electrode, the third electrode and the fourth electrode for performing a signal charge transferring operation and a signal charge increasing operation, wherein the first electrode, the second electrode, the third electrode and the fourth electrode are formed between the photoelectric conversion portion and the voltage conversion portion and provided so as not to overlap with at least a part of the photoelectric conversion portion in plan view, and at least the photoelectric conversion portion, the voltage conversion portion, the first electrode, the second electrode, the third electrode and the fourth electrode are included in one pixel.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIG. 2 is a sectional view showing the structure of the CMOS image sensor according to the first embodiment of the present invention;

FIG. 3 is a potential diagram in the CMOS image sensor according to the first embodiment of the present invention;

FIG. 4 is a plan view showing a pixel in the CMOS image sensor according to the first embodiment of the present invention;

FIG. 5 is a circuit diagram showing a circuit structure of the CMOS image sensor according to the first embodiment of the present invention;

FIG. 6 is a signal waveform diagram for illustrating an electron transferring operation of the CMOS image sensor according to the first embodiment of the present invention;

FIG. 7 is a potential diagram for illustrating the electron transferring operation of the CMOS image sensor according to the first embodiment of the present invention;

FIG. 8 is a signal waveform diagram for illustrating an electron multiplying operation of the CMOS image sensor according to the first embodiment of the present invention;

FIG. 9 is a potential diagram for illustrating the electron multiplying operation of the CMOS image sensor according to the first embodiment of the present invention;

FIG. 10 is another signal waveform diagram for illustrating the electron multiplying operation of the CMOS image sensor according to the first embodiment of the present invention;

FIG. 11 is another potential diagram for illustrating the electron multiplying operation of the CMOS image sensor according to the first embodiment of the present invention;

FIG. 12 is a signal waveform diagram for illustrating an electron multiplying operation of a CMOS image sensor according to a second embodiment of the present invention;

FIG. 13 is a potential diagram for illustrating the electron multiplying operation of the CMOS image sensor according to the second embodiment of the present invention;

FIG. 14 is a sectional view showing a structure of a CMOS image sensor according to a third embodiment of the present invention;

FIG. 15 is a potential diagram in the CMOS image sensor according to the third embodiment of the present invention;

FIG. 16 is a sectional view showing a structure of a CMOS image sensor according to a fourth embodiment of the present invention;

FIG. 17 is a potential diagram in the CMOS image sensor according to the fourth embodiment of the present invention;

FIG. 18 is a signal waveform diagram for illustrating an electron transferring operation of the CMOS image sensor according to the fourth embodiment of the present invention;

FIG. 19 is a potential diagram for illustrating the electron transferring operation of the CMOS image sensor according to the fourth embodiment of the present invention;

FIG. 20 is a signal waveform diagram for illustrating an electron multiplying operation of the CMOS image sensor according to the fourth embodiment of the present invention; and

FIG. 21 is a potential diagram for illustrating the electron multiplying operation of the CMOS image sensor according to the fourth embodiment of the present invention.

### DESCRIPTION OF THE PREFERRED EMBODIMENTS

Embodiments of the present invention will be hereinafter described with reference to the drawings.

### First Embodiment

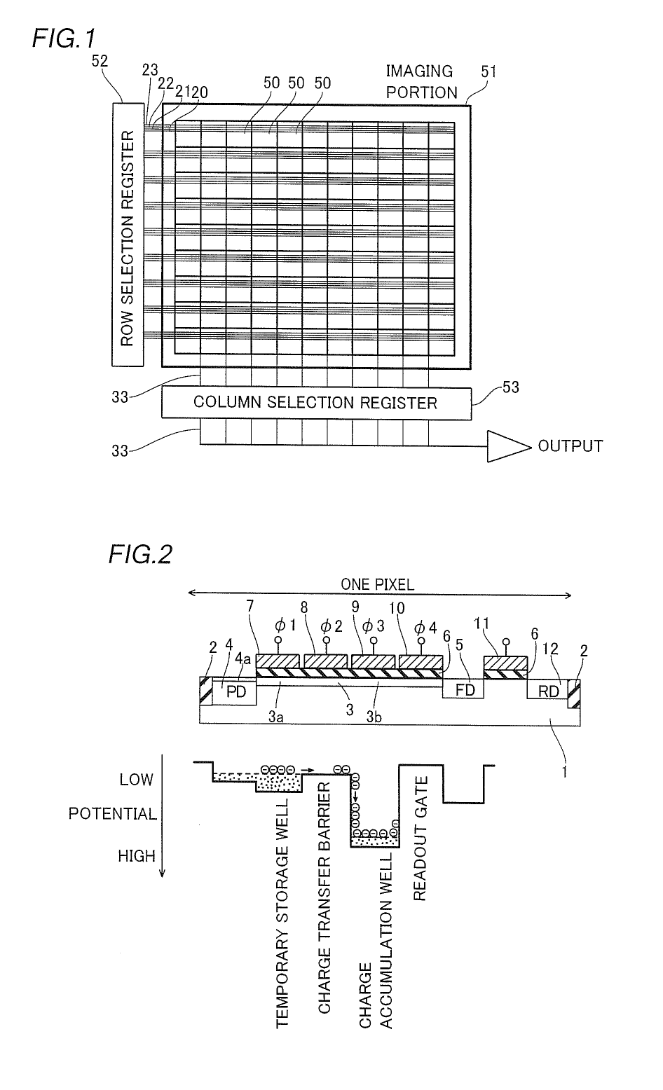

A structure of a CMOS image sensor according to a first embodiment of the present invention will be now described with reference to FIGS. 1 to 5. The first embodiment of the present invention is applied to an active CMOS image sensor employed as an exemplary image sensor.

The CMOS image sensor according to the first embodiment comprises an imaging portion 51 including a plurality of pixels 50 arranged in the form of a matrix, a row selection register 52 and a column selection register 53, as shown in FIG. 1.

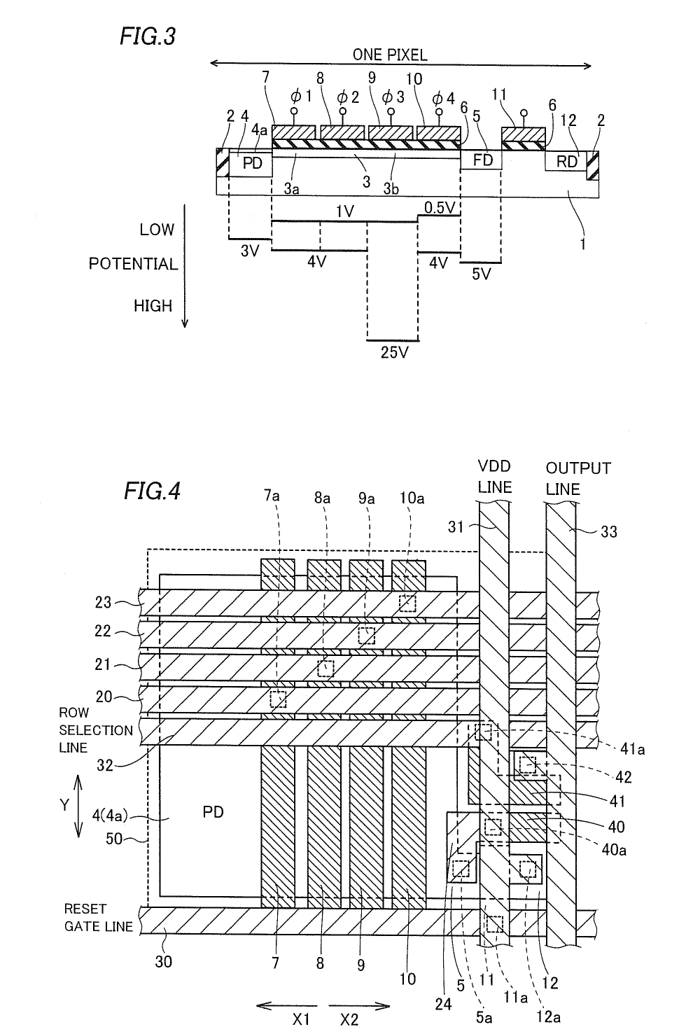

As to a sectional structure of the pixels 50 of the CMOS image sensor according to the first embodiment, element isolation regions 2 for isolating the pixels 50 from each other are formed on a surface of a p-type silicon substrate 1, as shown in FIGS. 2 and 3. On the surface of the p-type silicon substrate 1 provided with each pixel 50 enclosed with a corresponding element isolation region 2, a photodiode (PD) portion 4 consisting of an n-type impurity region and a floating diffusion (FD) region 5 consisting of an n⁺-type impurity region are formed at a prescribed interval, to hold a transfer channel 3 consisting of an n⁻-type impurity region therebetween. A p⁺-type impurity region 4a is formed on a surface of the photodiode portion 4. Thus, the photodiode portion 4 is employed as a buried photodiode. The photodiode portion 4 and the floating diffusion region 5 are examples of the “photoelectric conversion portion” and the “voltage conversion portion” in the present invention respectively.

The photodiode portion 4 has a function of generating electrons in response to the quantity of incident light and storing the generated electrons. The photodiode portion 4 is formed to be adjacent to the corresponding element isolation region 2 as well as to the transfer channel 3. The floating diffusion region 5 has an impurity concentration (n⁺) higher than the impurity concentration (n⁻) of the transfer channel 3. The floating diffusion region 5 has a function of holding signal charges formed by transferred electrons and converting the signal charges to a voltage. The floating diffusion region 5 is formed to be adjacent to the corresponding element isolation region 2 as well as to the transfer channel 3. Thus, the floating diffusion region 5 is opposed to the photodiode portion 4 through the transfer channel 3.

A gate insulating film 6 is formed on an upper surface of the transfer channel 3. The gate insulating film 6 is an example of the “insulating film” in the present invention. This gate insulating film 6 is provided so as not to overlap with the photodiode portion 4 in plan view. On prescribed regions of an upper surface of the gate insulating film 6, four gate electrodes of transfer gate electrodes 7 and 8, a multiplier gate electrode 9 and a readout gate electrode 10 are formed between the photodiode portion 4 and the floating diffusion region 5 at prescribed intervals and provided so as not to overlap with the photodiode portion 4, in plan view.

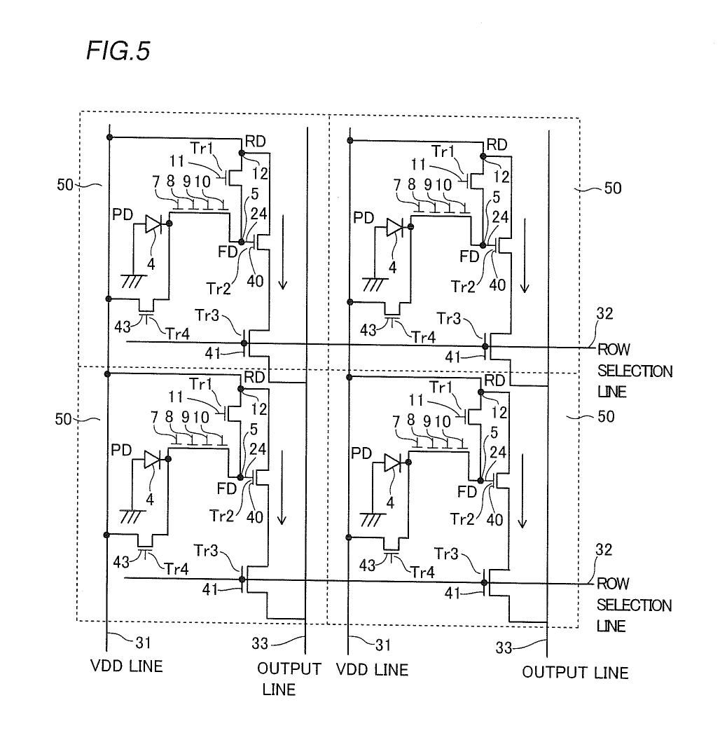

As to a planar structure of the transfer gate electrodes 7 and 8, the multiplier gate electrode 9 and the readout gate electrode 10, the transfer gate electrodes 7 and 8, the multiplier gate electrode 9 and the readout gate electrode 10 extend along arrow Y intersecting with an electron transfer direction (along arrow X2) and are formed at the prescribed intervals, as shown in FIG. 4. The photodiode portion 4 is formed on a side (along arrow X1) of the transfer gate electrode 7, opposite to a side (along arrow X2) on which the floating diffusion region 5 is formed, in plan view.

According to the first embodiment, the transfer gate electrode 7 is formed to be adjacent to the photodiode portion 4, and the transfer gate electrode 8 is formed between the transfer gate electrode 7 and the multiplier gate electrode 9. The readout gate electrode 10 is formed between the multiplier gate electrode 9 and the floating diffusion region 5. The readout gate electrode 10 is formed to be adjacent to the floating diffusion region 5. The transfer gate electrode 7, the transfer gate electrode 8, the multiplier gate electrode 9 and the readout gate electrode 10 are examples of the “first electrode”, the “fourth electrode”, the “second electrode” and the “third electrode” in the present invention respectively.

Wiring layers 20, 21, 22 and 23 supplying clock signals φ1, φ2, φ3 and φ4 for voltage control are electrically connected to the transfer gate electrodes 7 and 8, the multiplier gate electrode 9 and the readout gate electrode 10 through contact portions 7a, 8a, 9a and 10a respectively. The wiring layers 20, 21, 22 and 23 are formed every row, and electrically connected to the transfer gate electrodes 7 and 8, the multiplier gate electrodes 9 and the readout gate electrodes 10 of the plurality of pixels 50 forming each row respectively. A signal line 24 for extracting a signal through a contact portion 5a is electrically connected to the floating diffusion region 5.

When ON-state (high-level) clock signals φ1, φ2 and φ4 are supplied to the transfer gate electrodes 7 and 8 and the readout gate electrode 10 respectively, voltages of about 2.9 V are applied to the transfer gate electrodes 7 and 8 and the readout gate electrode 10, as shown in FIG. 3. Thus, portions of the transfer channel 3 located under the transfer gate electrodes 7 and 8 and the readout gate electrode 10 respectively are controlled to potentials of about 4 V.

When an ON-state (high-level) clock signal φ3 is supplied to the multiplier gate electrode 9, a voltage of about 24 V is applied to the multiplier gate electrode 9. Thus, the portion of the transfer channel 3 located under the transfer gate electrode 9 is controlled to a high potential of about 25 V.

When OFF-state (low-level) clock signals φ1, φ2 and φ3 are supplied to the transfer gate electrodes 7 and 8 and the multiplier gate electrode 9 respectively, voltages of about 0 V are applied to the transfer gate electrodes 7 and 8 and the multiplier gate electrode 9. Thus, the portions of the transfer channel 3 located under the transfer gate electrodes 7 and 8 and the multiplier gate electrode 9 respectively are controlled to potentials of about 1 V.

According to the first embodiment, when an OFF-state (low-level) clock signal φ4 is supplied to the readout gate electrode 10, a voltage of about −2 V is applied to the readout gate electrode 10. Thus, the portion of the transfer channel 3 located under the readout gate electrode 10 is controlled to a potential of about 0.5 V.

The photodiode portion 4 and the floating diffusion region 5 are controlled to potentials of about 3 V and about 5 V respectively.

As shown in FIG. 2, when the portion (electron storage portion (temporary storage well) 3a) of the transfer channel 3 located under the transfer gate electrode 7 is supplied with an ON-state (high-level) clock signal φ1, an electric field temporarily storing electrons is formed in the portion of the transfer channel 3 located under the transfer gate electrode 7.

The portion of the transfer channel 3 located under the transfer gate electrode 8 has a function of transferring the electrons stored in the electron storage portion 3a to the electron multiplying portion 3b and transferring the electrons stored in the electron multiplying portion 3b to the electron storage portion 3a when the ON-state (high-level) clock signal φ2 is supplied to the transfer gate electrode 8. The electron multiplying portion 3b is an example of the “increasing portion” in the present invention. The portion of the transfer channel 3 located under the transfer gate electrode 8 functions as a charge transfer barrier dividing the electron storage portion 3a and the electron multiplying portion 3b from each other when the OFF-state (low-level) clock signal φ2 is supplied to the transfer gate electrode 8.

When the ON-state (high-level) clock signal φ3 is supplied to the multiplier gate electrode 9, the portion (electron multiplying portion 3b) of the transfer channel 3 located under the multiplier gate electrode 9 is controlled to the potential of about 25 V, so that a high electric field impact-ionizing electrons and multiplying (increasing) the number thereof is formed in the portion (electron multiplying portion 3b) of the transfer channel 3 located under the multiplier gate electrode 9. The impact ionization of the electrons is caused on the boundary between the portion (electron multiplying portion 3b) of the transfer channel 3 located under the multiplier gate electrode 9 and the portion of the transfer channel 3 located under the transfer gate electrode 8.

The portion of the transfer channel 3 located under the readout gate electrode 10 has a function of transferring the electrons stored in the transfer channel 3 (electron multiplying portion 3b) to the floating diffusion region 5 when the ON-state (high-level) clock signal φ4 is supplied to the readout gate electrode 10. Further, the portion of the transfer channel 3 located under the readout gate electrode 10 has a function of dividing the transfer channel 3 (electron multiplying portion 3b) and the floating diffusion region 5 from each other when the OFF-state (low-level) clock signal φ4 is supplied to the readout gate electrode 10. The CMOS image sensor according to the first embodiment is so formed that the portions of the transfer channel 3 located under the readout gate electrode 10 has the lowest potential when the OFF-state (low-level) clock signals φ1, φ2, φ3 and φ4 are supplied to the transfer gate electrodes 7 and 8, the multiplier gate electrode 9 and the readout gate electrode 10 respectively.

As shown in FIGS. 4 and 5, each pixel 50 includes the transfer gate electrodes 7 and 8, the multiplier gate electrode 9, the readout gate electrode 10, a reset gate transistor Tr1 including a reset gate electrode 11, an amplification transistor Tr2 and a pixel selection transistor Tr3 and a PD portion reset gate transistor Tr4. A reset gate line 30 is connected to the reset gate electrode 11 of the reset gate transistor Tr1 through a contact portion 11a, to supply a reset signal. The photodiode portion 4 is provided on a region enclosed with the reset gate line 30 and the transfer gate electrode 7 in plan view. A drain (reset drain 12) of the reset gate transistor Tr1 is connected to a power supply potential (VDD) line 31 through another contact portion 12a. The floating diffusion region 5 constituting sources of the reset gate transistor Tr1 and the readout gate electrode 10 and a gate 40 of the amplification transistor Tr2 are connected with each other by a signal line 24 through the contact portion 5a and a contact portion 40a. A drain of the pixel selection transistor Tr3 is connected to a source of the amplification transistor Tr2. A row selection line 32 and an output line 33 are connected to a gate 41 and a source of the pixel selection transistor Tr3 through contact portions 41a and 42 respectively. The PD portion reset gate transistor Tr4 includes a reset gate electrode 43 and a PD portion reset signal is supplied to the reset gate electrode 43. The CMOS image sensor according to the first embodiment has the aforementioned circuit structure, so that the readout gate electrodes 10 are on-off controlled every row, while the remaining gate electrodes other than the readout gate electrodes 10 are simultaneously on-off controlled with respect to the overall pixels 50.

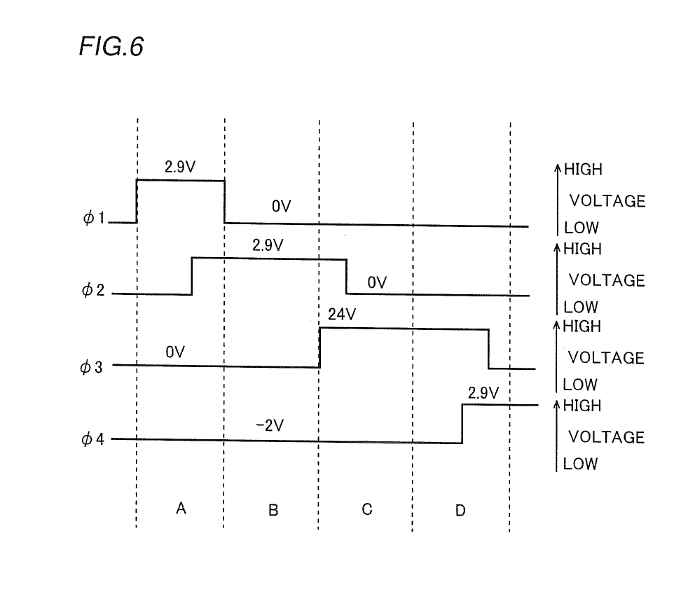

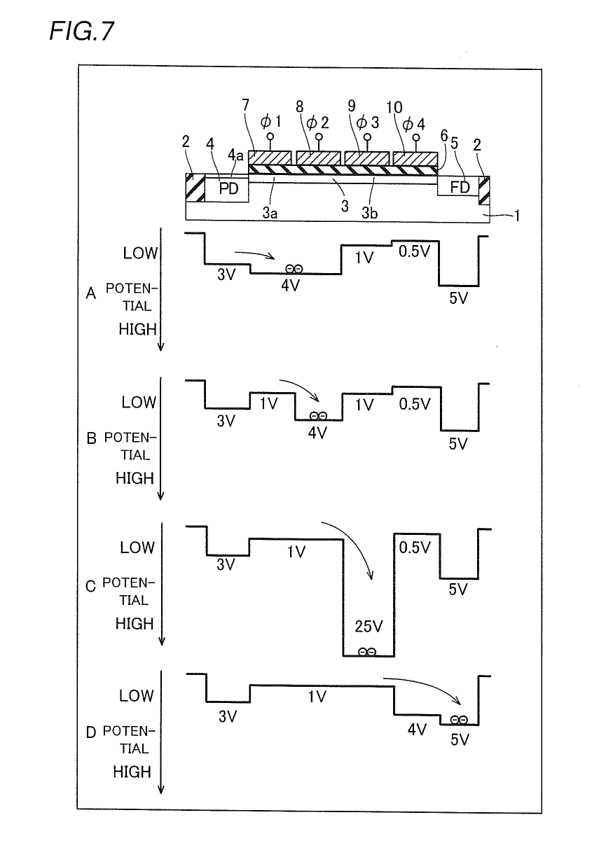

An electron transferring operation of the CMOS image sensor according to the first embodiment will be now described with reference to FIGS. 6 and 7.

In a period A shown in FIG. 6, the transfer gate electrode 7 is brought into an ON state, thereby controlling the portion of the transfer channel 3 located under the transfer gate electrode 7 to a potential of about 4 V, as shown in FIG. 7. At this time, the photodiode portion 4 is controlled to a potential of about 3 V, and hence the electrons generated by and stored in the photodiode portion 4 are transferred from the photodiode portion 4 to the portion of the transfer channel 3 located under the transfer gate electrode 7. Then, the transfer gate electrode 8 is brought into an ON state while the transfer gate electrode 7 remains in an ON state, so that the portions of the transfer channel 3 located under the transfer gate electrodes 7 and 8 are controlled to about potentials of about 4 V. Thus, the electrons having been transferred to the portion of the transfer channel 3 located under the transfer gate electrode 7 are also transferred to the portion of the transfer channel 3 located under the transfer gate electrode 8.

In a period B shown in FIG. 6, the transfer gate electrode 7 is brought into an OFF state while the transfer gate electrode 8 is in an ON state to control the portion of the transfer channel 3 located under the transfer gate electrode 7 to a potential of about 1 V while the portion of the transfer channel 3 located under the transfer gate electrode 8 remains controlled to the potential of about 4 V. Thus, the electrons having been transferred to the portion of the transfer channel 3 located under the transfer gate electrode 7 are transferred to the portion of the transfer channel 3 located under the transfer gate electrode 8.

In a period C shown in FIG. 6, the multiplier gate electrode 9 is brought into an ON state and the transfer gate electrode 8 is thereafter brought into an OFF state to control the portion (electron multiplying portion 3b) of the transfer channel 3 located under the multiplier gate electrode 9 to a high potential of about 25 V and to thereafter control the portion of the transfer channel 3 located under the transfer gate electrode 8 to a potential of about 1 V, as shown in FIG. 7. Therefore, the electrons having been transferred to the portion of the transfer channel 3 located under the transfer gate electrode 8 are transferred to the portion, controlled to the potential (about 25 V) higher than the potential (about 1 V) of the portion of the transfer channel 3 located under the transfer gate electrode 7, of the transfer channel 3 located under the multiplier gate electrode 9.

In a period D shown in FIG. 6, the readout gate electrode 10 is brought into an ON state and the multiplier gate electrode 9 is thereafter brought into an OFF state while the electrons are stored in the portion (electron multiplying portion 3b) of the transfer channel 3 located under the multiplier gate electrode 9 to control the portion of the transfer channel 3 located under the readout gate electrode 10 to a potential of about 4 V and to thereafter control the portion of the transfer channel 3 located under the multiplier gate electrode 9 to a potential of about 1 V, as shown in FIG. 7. Therefore, the electrons stored in the portion of the transfer channel 3 located under the multiplier gate electrode 9 are transferred to the floating diffusion region 5, controlled to the potential (about 5 V) higher than the potential (about 1 V) of the portion of the transfer channel 3 located under the multiplier gate electrode 9, through the portion, controlled to the potential of about 4 V, of the transfer channel 3 located under the readout gate electrode 10.

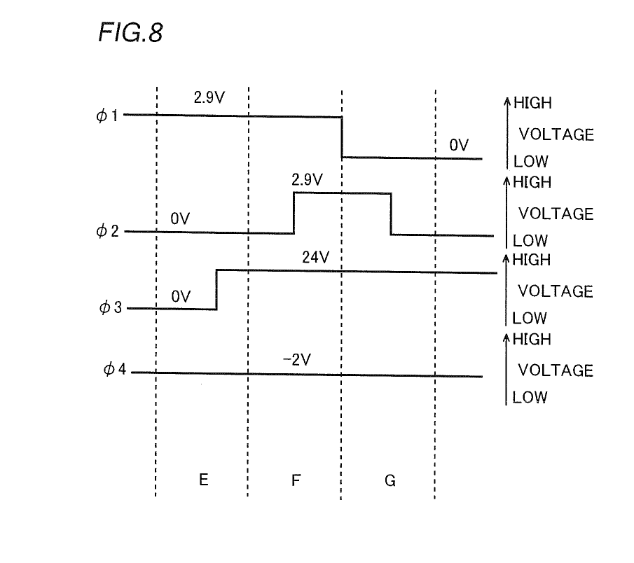

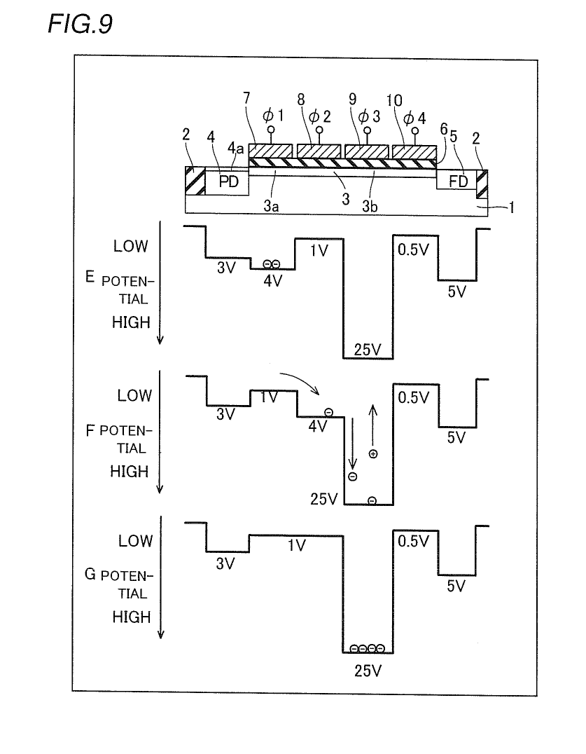

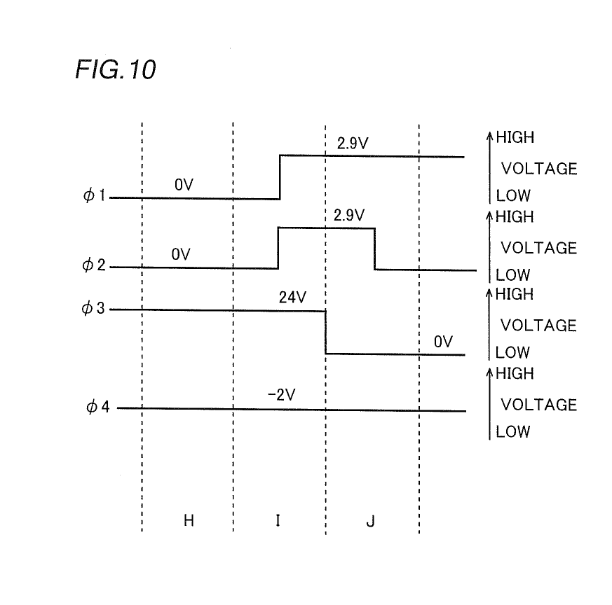

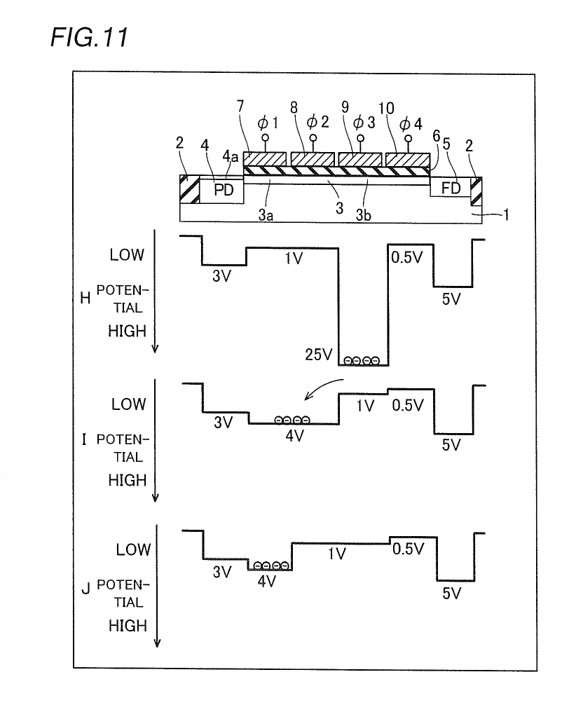

FIGS. 8 and 10 are signal waveform diagrams for illustrating an electron multiplying operation of the CMOS image sensor according to the first embodiment of the present invention. FIGS. 9 and 11 are potential diagrams for illustrating the electron multiplying operation of the CMOS image sensor according to the first embodiment of the present invention. The electron multiplying operation of the CMOS image sensor according to the first embodiment will be now described with reference to FIGS. 7 to 11.

After the operation of transferring the electrons to the portion of the transfer channel 3 located under the transfer gate electrode 7 in the period A shown in FIG. 7, the multiplier gate electrode 9 is bought into an ON state while the portion of the transfer channel 3 located under the transfer gate electrode 7 holds the electrons in a period E shown in FIG. 8, as shown in FIG. 9.

In a period F shown in FIG. 8, the transfer gate electrode 8 is brought into an ON state and the transfer gate electrode 7 is thereafter brought into an OFF state to control the portion of the transfer channel 3 located under the transfer gate electrode 7 to a potential of about 1 V and to control the portion of the transfer channel 3 located under the transfer gate electrode 8 to a potential of about 4 V, as shown in FIG. 9. Therefore, the electrons stored in the portion (electron storage portion 3a) of the transfer channel 3 located under the transfer gate electrode 7 are transferred to the portion (electron multiplying portion 3b), controlled to the high potential (about 25 V), of the transfer channel 3 located under the multiplier gate electrode 9 through the portion (having the about 4 V) of the transfer channel 3 located under the transfer gate electrode 8. The electrons transferred to the portion (electron multiplying portion 3b) of the transfer channel 3 located under the multiplier gate electrode 9 obtain energy from the high electric field when moving through the boundary between the portions of the transfer channel 3 located under the multiplier gate electrode 9 and the transfer gate electrode 8. The electrons having high energy collide with silicon atoms to generate electrons and holes (impact ionization). Thereafter the electrons generated by the impact ionization are stored in the portion (electron multiplying portion 3b) of the transfer channel 3 located under the multiplier gate electrode 9 by the electric field.

Then, in a period G shown in FIG. 8, the transfer gate electrode 8 is brought into an OFF state to control the portion of the transfer channel 3 located under the transfer gate electrode 8 to a potential of about 1 V, as shown in FIG. 9.

The transfer gate electrodes 7 and 8 are brought into ON states in a period I from the state where the portion (electron multiplying portion 3b) of the transfer channel 3 located under the multiplier gate electrode 9 holds the electrons in a period H shown in FIG. 10, as shown in FIG. 11. Thus, the portions of the transfer channel 3 located under the transfer gate electrodes 7 and 8 respectively are controlled to potentials of about 4 V. From this state, the multiplier gate electrode 9 is brought into an OFF state, to control the potential of the transfer channel 3 located under the multiplier gate electrode 9 to a potential of about 1 V. Thus, the electrons having been stored in the portion (electron multiplying portion 3b) of the transfer channel 3 located under the multiplier gate electrode 9 are transferred to the portions (having the potentials of about 4 V) of the transfer channel 3 located under the transfer gate electrodes 7 and 8 respectively.

In a period J shown in FIG. 10, the transfer gate electrode 8 is brought into an OFF state to control the potential of the portion of the transfer channel 3 located under the transfer gate electrode 8 to a potential of about 1 V, as shown in FIG. 11. Thus, the electrons are transferred to the portion (electron storage portion 3a) of the transfer channel 3 located under the transfer gate electrode 7. Thereafter the CMOS image sensor according to the first embodiment repeats the multiplying operation in the aforementioned periods E to J a plurality of times (about 400 times, for example), thereby multiplying the electrons transferred from the photodiode portion 4 to about 2000 times. According to the first embodiment, the potential (about 0.5 V) of the portion of the transfer channel 3 located under the readout gate electrode 10 is controlled to be lower than the potential (about 1 V) of the portion of the transfer channel 3 located under the transfer gate electrode 8 in the electron transferring and multiplying periods of the periods E to J shown in FIGS. 9 and 11.

According to the first embodiment, as hereinabove described, the CMOS image sensor is provided with the four gate electrodes of the transfer gate electrodes 7 and 8, the multiplier gate electrode 9 and the readout gate electrode 10 in each pixel, whereby the number of the gate electrodes is one gate electrode smaller than the number of the gate electrodes of the conventional CMOS image sensor comprising the five gate electrodes, and hence the area of the photodiode portion 4 can be increased when the pixel sizes are the same. The transfer gate electrodes 7 and 8, the multiplier gate electrode 9 and the readout gate electrode 10 are provided between the photodiode portion 4 and the floating diffusion region 5 so as not to overlap with the photodiode portion 4 in plan view, whereby no gate electrode is formed on the surface of the photodiode portion 4 and hence a buried photodiode formed with the p⁺-type impurity region 4a on the surface of the photodiode portion 4 can be formed. The four gate electrodes of the transfer gate electrodes 7 and 8, the multiplier gate electrode 9 and the readout gate electrode 10 are provided so as not to overlap with the impurity region 4a in plan view. The impurity region 4a is an example of the “impurity region” in the present invention. Thus, a dark current can be inhibited from generating on the surface of the photodiode portion 4 resulting from defects by an interface state on the surface of the photodiode portion 4. No gate electrode is formed on the surface of the photodiode portion 4, whereby reduction of the sensitivity of the photodiode portion 4 resulting from absorption of light by the gate electrode can be suppressed and hence the sensitivity of the image sensor can be improved dissimilarly to the case where the gate electrode is formed on the surface of the photodiode portion 4.

According to the first embodiment, as hereinabove described, the transfer gate electrode 7 is provided to be adjacent to the photodiode portion 4, the multiplier gate electrode 9 is provided to be adjacent to a side of the transfer gate electrode 8 opposite to the photodiode portion 4, whereby the electrons can be easily multiplied by repeating movement of the electrons between the portion (electron storage portion 3a) of the transfer channel 3 located under the transfer gate electrode 7 and the portion (electron multiplying portion 3b) of the transfer channel 3 located under the multiplier gate electrode 9.

According to the first embodiment, as hereinabove described, the electron multiplying operation (see FIG. 9), in which the transfer gate electrodes 7 and 8 are controlled so as to transfer the electrons stored in the portion (electron storage portion 3a) of the transfer channel 3 located under the transfer gate electrode 7 to the portion (electron multiplying portion 3b) of the transfer channel 3 located under the multiplier gate electrode 9 while forming the electric field impact-ionizing the electrons by the multiplier gate electrode 9, and the electron transferring operation (see FIG. 11), in which the transfer gate electrodes 7 and 8 and the multiplier gate electrode 9 are controlled so as to transfer the electrons multiplied by the electric field by the multiplier gate electrode 9 to the portion (electron storage portion 3a) of the transfer channel 3 located under the transfer gate electrode 7 are alternately performed. Thus, the electron multiplying operation can be performed a plurality of times (about 400 times, for example), and hence the electron multiplication factor can be improved. Consequently, the number of the electrons transferred from the photodiode portion 4 can be increased to about 2000 times.

According to the first embodiment, as hereinabove described, the potential (about 0.5 V) of the portion of the transfer channel 3 located under the readout gate electrode 10 is controlled to be lower than the potential (about 1 V) of the portion of the transfer channel 8 located under the transfer gate electrode 8 in the electron multiplying operation (see FIG. 9), in which the electrons stored in the portion (electron storage portion 3a) of the transfer channel 3 located under the transfer gate electrode 7 are transferred to the portion (electron multiplying portion 3b) of the transfer channel 3 located under the multiplier gate electrode 9 while forming the electric field impact-ionizing the electrons by the multiplier gate electrode 9, and the electron transferring operation (see FIG. 11), in which the electrons multiplied by the electric field by the multiplier gate electrode 9 are transferred to the portion (electron storage portion 3a) of the transfer channel 3 located under the transfer gate electrode 7. In the electron transferring operation and the electron multiplying operation, thus, the electrons can be inhibited from leaking toward the floating diffusion region 5 over a barrier (charge barrier) by the potential formed in the portion of the transfer channel 3 located under the readout gate electrode 10, and hence the number of the transferred electrons can be prevented from dispersion. Consequently, the CMOS image sensor can correctly read data.

### Second Embodiment

Referring to FIGS. 7, 12 and 13, an ON-state (high-level) clock signal φ1 is always supplied to a transfer gate electrode 7 in an electron multiplying operation of a CMOS image sensor according to a second embodiment, dissimilarly to the aforementioned first embodiment. A structure of the CMOS image sensor according to the second embodiment is similar to that of the CMOS image sensor according to the aforementioned first embodiment.

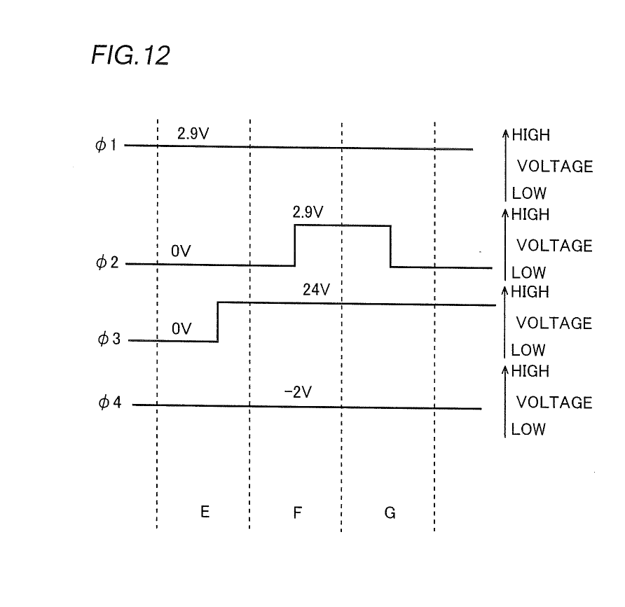

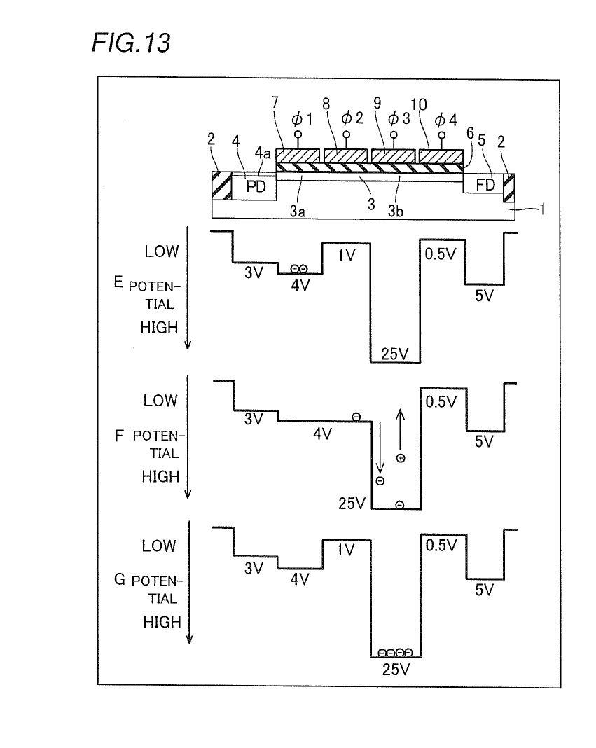

After an operation of transferring electrons to a portion of the transfer channel 3 located under the transfer gate electrode 7 in a period A shown in FIG. 7, a multiplier gate electrode 9 is brought into an ON-state while holding the electrons in the portion of the transfer channel 3 located under the transfer gate electrode 7 in a period E shown in FIG. 12, as shown in FIG. 13.

In a period F shown in FIG. 12, a transfer gate electrode 8 is brought into an ON-state while the transfer gate electrode 7 remains in the ON-state, as shown in FIG. 13. Then the portions of the transfer channel 3 located under the transfer gate electrodes 7 and 8 are controlled to potentials of about 4 V. Thus, the transfer gate electrode 8 is brought into the ON-state while the transfer gate electrode 7 remains in the ON-state, whereby control of the transfer gate electrodes can be simplified dissimilarly to the case where the transfer gate electrode 8 is brought into an ON-state after bringing the transfer gate electrode 7 into an OFF-state similarly to the aforementioned first embodiment. The electrons stored in the portion (electron storage portion 3a) of the transfer channel 3 located under the transfer gate electrode 7 are transferred to a portion (electron multiplying portion 3b), controlled to a high potential (about 25 V), of the transfer channel 3 located under the multiplier gate electrode 9 through the portion (having the potential of about 4 V) of the transfer channel 3 located under the transfer gate electrode 8. The electrons transferred to the portion (electron multiplying portion 3b) of the transfer channel 3 located under the multiplier gate electrode 9 obtain energy from a high electric field when moving through the boundary between the portions of the transfer channel 3 located under the multiplier gate electrode 9 and the transfer gate electrode 8. The electrons having high energy collide with silicon atoms to generate electrons and holes (impact ionization). Thereafter the electrons generated by the impact ionization are stored in the portion (electron multiplying portion 3b) of the transfer channel 3 located under the multiplier gate electrode 9 by the electric field.

In a period G shown in FIG. 12, the transfer gate electrode 8 is brought into an OFF state to control the potential of the portion of the transfer channel 3 located under the transfer gate electrode 8 to a potential of about 1 V, as shown in FIG. 13.

The remaining operations of the CMOS image sensor according to the second embodiment are similar to those of the CMOS image sensor according to the aforementioned first embodiment.

The effects of the second embodiment are similar to those of the aforementioned first embodiment.

### Third Embodiment

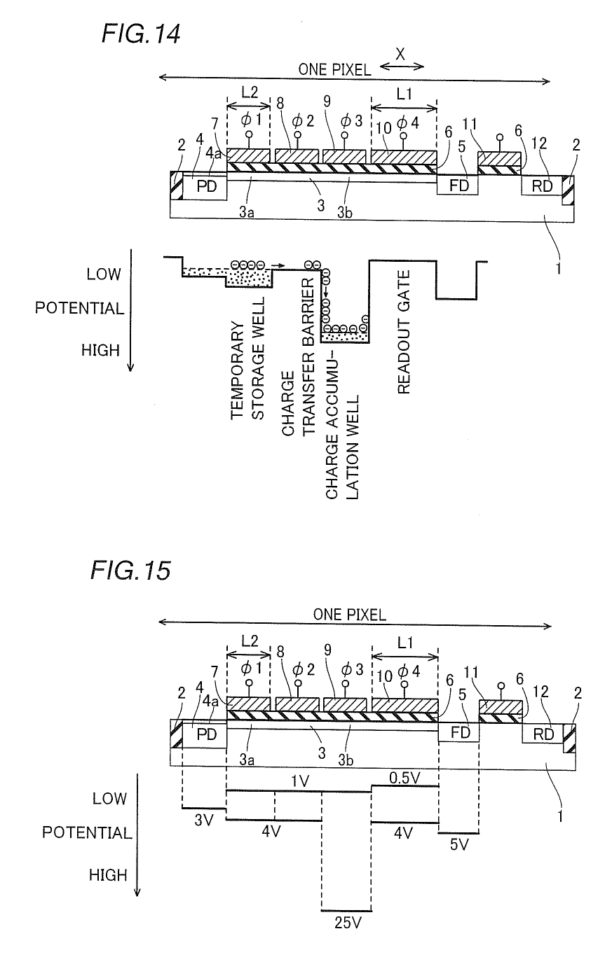

Referring to FIGS. 14 and 15, the gate length of a readout gate electrode 10 is larger than the gate length of each of the remaining gate electrodes in a CMOS image sensor according to a third embodiment, dissimilarly to the aforementioned first embodiment.

According to the third embodiment, the gate length L1 of the readout gate electrode 10 is larger than the gate length L2 of each of the remaining gate electrodes other than the readout gate electrode 10, as shown in FIGS. 14 and 15. When an OFF-state (low-level) clock signal φ4 is supplied to the readout gate electrode 10, a voltage of about −1.5 V is applied to the readout gate electrode 10. At this time, a portion of the transfer channel 3 located under the readout gate electrode 10 is controlled to a potential of about 0.5 V. The remaining structure and operations of the CMOS image sensor according to the third embodiment are similar to those of the CMOS image sensor according to aforementioned first embodiment.

According to the third embodiment, as hereinabove described, the gate length L1 of the readout gate electrode 10 is larger than the gate length L2 of each of the remaining gate electrodes other than the readout gate electrode 10, whereby the length (along arrow X in FIG. 14) of a barrier (charge barrier) by the potential formed in the portion of the transfer channel 3 located under the readout gate electrode 10 is also increased in proportion to the gate length of the readout gate electrode 10. In an electron multiplying operation and an electron transferring operation, thus, electrons can be further inhibited from leaking toward an floating diffusion region 5 over the barrier (charge barrier) formed in the portion of the transfer channel 3 located under the readout gate electrode 10 dissimilarly to the aforementioned first and second embodiments. Consequently, the number of electrons transferred from an electron storage portion 3a to the floating diffusion region 5 can be further prevented from dispersion, and hence the CMOS image sensor can correctly read data.

The remaining effects of the third embodiment are similar to those of the aforementioned first embodiment.

### Fourth Embodiment

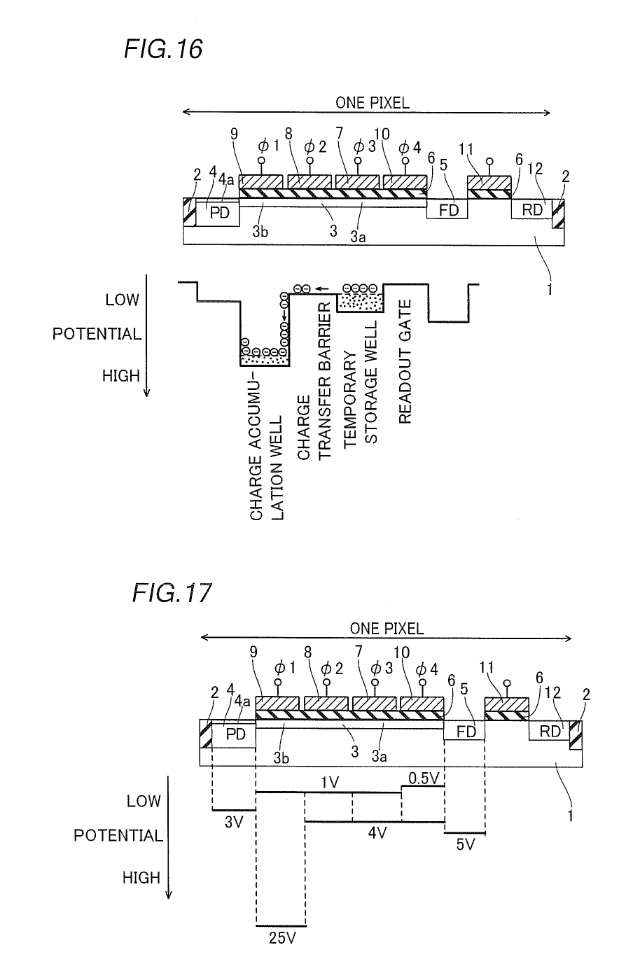

Referring to FIGS. 16 and 17, a multiplier gate electrode 9 is provided to be adjacent to a photodiode portion 4 in a CMOS image sensor according to a fourth embodiment, dissimilarly to the aforementioned first embodiment.

According to the fourth embodiment, the multiplier gate electrode 9 is formed to be adjacent to the photodiode portion 4 and provided on a side opposite to a transfer gate electrode 7 and a readout gate electrode 10 with respect to a transfer gate electrode 8, as shown in FIGS. 16 and 17. The photodiode portion 4 is formed on a side of the multiplier gate electrode 9 opposite to a side on which a floating diffusion region 5 is formed, in plan view. The transfer gate electrode 7 is provided between the transfer gate electrode 8 and the readout gate electrode 10. Following this, positions of an electron storage portion 3a and an electron multiplying portion 3b in the transfer channel 3 are also reversed. Clock signals φ1, φ2, φ3 and φ4 for voltage control are supplied to the multiplier gate electrode 9, the transfer gate electrodes 8 and 7 and the readout gate electrode 10 respectively.

The remaining structure of the CMOS image sensor according to the fourth embodiment is similar to that of the CMOS image sensor according to the aforementioned first embodiment.

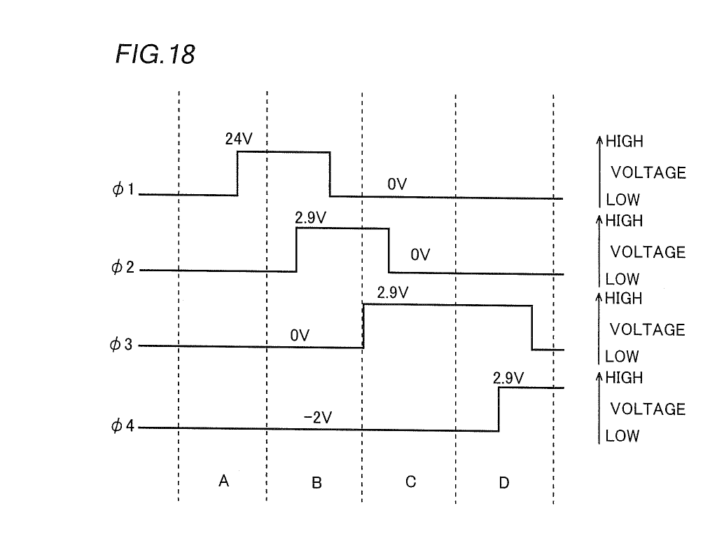

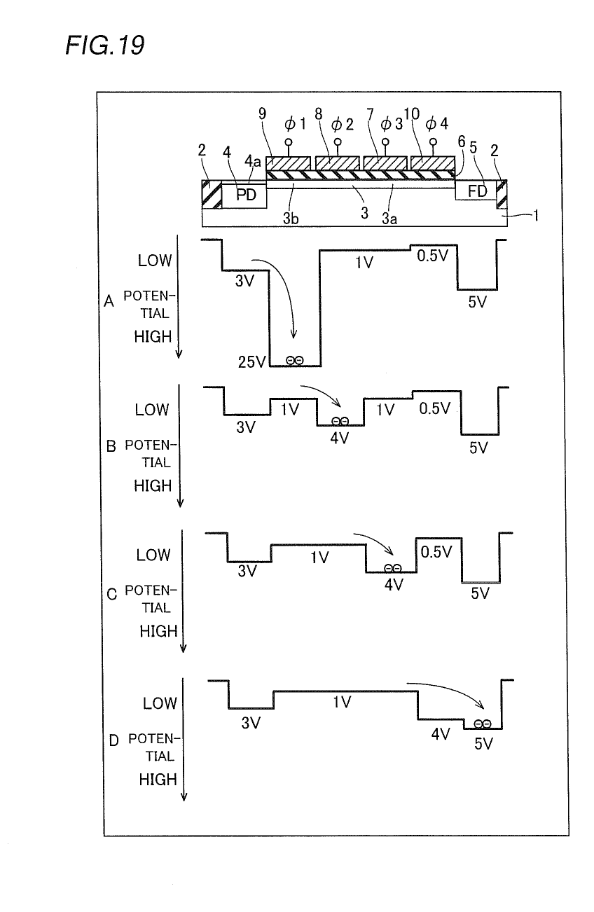

An electron transferring operation of the CMOS image sensor according to the fourth embodiment will be now described with reference to FIGS. 18 and 19.

In a period A shown in FIG. 18, the multiplier gate electrode 9 is brought into an ON state, thereby controlling a portion of the transfer channel 3 located under the multiplier gate electrode 9 to a potential of about 25 V, as shown in FIG. 19. At this time, the photodiode portion 4 is controlled to a potential of about 3 V, and hence the electrons stored in the photodiode portion 4 are transferred to the portion of the transfer channel 3 located under the multiplier gate electrode 9.

In a period B shown in FIG. 18, the transfer gate electrode 8 is brought into an ON state and the multiplier gate electrode 9 is brought into an OFF state to control the portion of the transfer channel 3 located under the transfer gate electrode 8 to a potential of about 4 V and to control the portion of the transfer channel 3 located under the multiplier gate electrode 9 to a potential of about 1 V, as shown in FIG. 19. Thus, the electrons stored in the portion of the transfer channel 3 located under the multiplier gate electrode 9 are transferred to the portion, controlled to the potential (about 4 V) higher than the potential (about 1 V) of the portion of the transfer channel 3 located under the multiplier gate electrode 9, of the transfer channel 3 located under the transfer gate electrode 8.

In a period C shown in FIG. 18, the transfer gate electrode 7 is brought into an ON state and the transfer gate electrode 8 is brought into an OFF state to control the portion of the transfer channel 3 located under the transfer gate electrode 7 to a potential of about 4 V and to control the portion of the transfer channel 3 located under the transfer gate electrode 8 to a potential of about 1 V, as shown in FIG. 19. Therefore, the electrons having been transferred to the portion of the transfer channel 3 located under the transfer gate electrode 8 are transferred to the portion, controlled to the potential (about 4 V) higher than the potential (about 1 V) of the portion of the transfer channel 3 located under the transfer gate electrode 8, of the transfer channel 3 located under the transfer gate electrode 7. Thus, the electrons transferred from the photodiode portion 4 are temporarily stored in the portion (electron storage portion 3a) of the transfer channel 3 located under the transfer gate electrode 7.

In a period D shown in FIG. 18, the readout gate electrode 10 is brought into an ON state and the transfer gate electrode 7 is brought into an OFF state while the electrons are temporarily stored in the portion (electron storage portion 3a) of the transfer channel 3 located under the transfer gate electrode 7 to control the portion of the transfer channel 3 located under the readout gate electrode 10 to a potential of about 4 V and to control the portion of the transfer channel 3 located under the transfer gate electrode 7 to a potential of about 1 V, as shown in FIG. 19. Therefore, the electrons stored in the portion (electron storage portion 3a) of the transfer channel 3 located under the transfer gate electrode 7 are transferred to the floating diffusion region 5, controlled to the potential (about 5 V) higher than the potential (about 1 V) of the portion of the transfer channel 3 located under the transfer gate electrode 7, through the portion, controlled to the potential of about 4 V, of the transfer channel 3 located under the readout gate electrode 10.

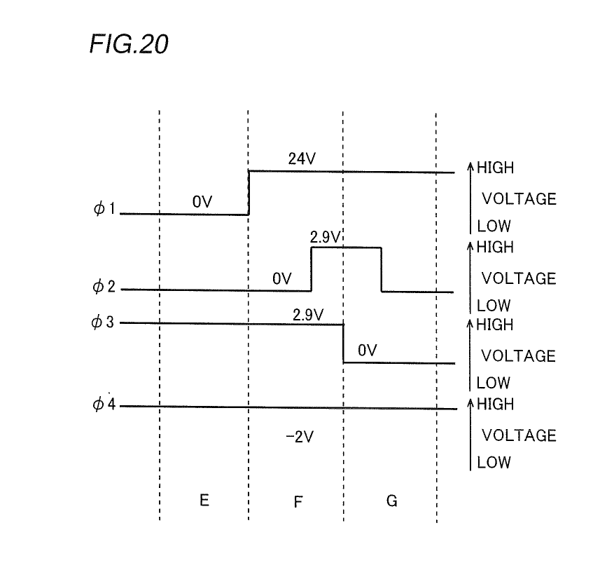

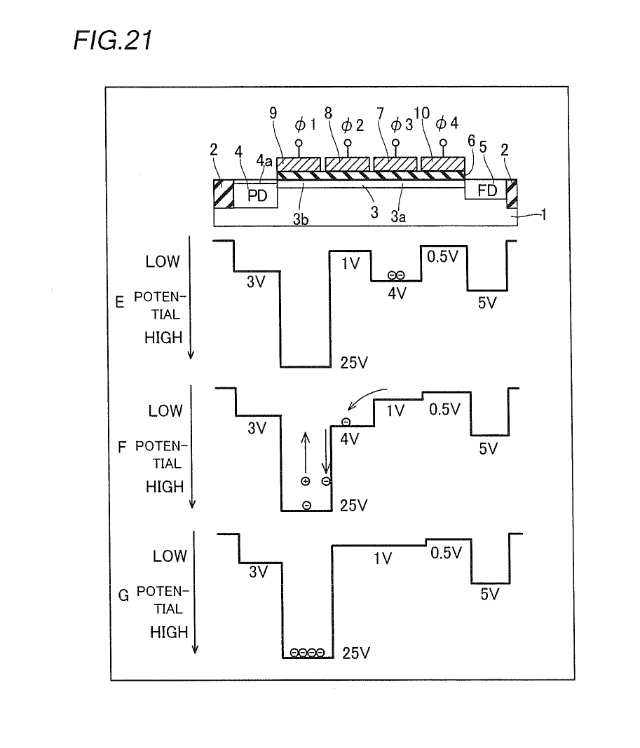

The electron multiplying operation of the CMOS image sensor according to the fourth embodiment will be now described with reference to FIGS. 20 and 21.

After the electron transferring operation in the period C shown in FIG. 19, the multiplier gate electrode 9 is bought into an ON state while the electrons are stored in the portion (electron storage portion 3a) of the transfer channel 3 located under the transfer gate electrode 7 to control the portion (electron multiplying portion 3b) of the transfer channel 3 located under the multiplier gate electrode 9 to a potential of about 25 in a period E shown in FIG. 20, as shown in FIG. 21.

In a period F shown in FIG. 20, the transfer gate electrode 8 is brought into an ON state and the transfer gate electrode 7 is brought into an OFF state to control the portion of the transfer channel 3 located under the transfer gate electrode 8 to a potential of about 4 V and to control the portion of the transfer channel 3 located under the transfer gate electrode 7 to a potential of about 1 V, as shown in FIG. 21. Therefore, the electrons stored in the portion of the transfer channel 3 located under the transfer gate electrode 7 are transferred to the portion, controlled to the potential (about 4 V) higher than the potential (about 1 V) of the portion of the transfer channel 3 located under the transfer gate electrode 7, of the transfer channel 3 located under the transfer gate electrode 8. The electrons transferred to the portion of the transfer channel 3 located under the transfer gate electrode 8 are transferred to the portion, controlled to the potential (about 25 V) higher than the potential (about 4 V) of the portion of the transfer channel 3 located under the transfer gate electrode 8, of the transfer channel 3 located under the multiplier gate electrode 9. The electrons transferred to the portion (electron multiplying portion 3b) of the transfer channel 3 located under the multiplier gate electrode 9 obtain energy from the high electric field when moving through the boundary between the portions of the transfer channel 3 located under the multiplier gate electrode 9 and the transfer gate electrode 8. The electrons having high energy collide with silicon atoms to generate electrons and holes (impact ionization). Thereafter the electrons generated by the impact ionization are stored in the portion (electron multiplying portion 3b) of the transfer channel 3 located under the multiplier gate electrode 9 by the electric field.

Then, in a period G shown in FIG. 20, the transfer gate electrode 8 is brought into an OFF state to control the portion of the transfer channel 3 located under the transfer gate electrode 8 to a potential of about 1 V, as shown in FIG. 21.

The electron transferring operation in the aforementioned periods B and C shown in FIG. 19 is performed, thereby transferring the electrons stored in the portion (electron multiplying portion 3b) of the transfer channel 3 located under the multiplier gate electrode 9 to the portion (electron storage portion 3a) of the transfer channel 3 located under the transfer gate electrode 7. Thereafter the CMOS image sensor repeats the multiplying operation in the aforementioned periods E to G and the transferring operation in the aforementioned periods B and C a plurality of times (about 400 times, for example), thereby multiplying the electrons transferred from the photodiode portion 4 to about 2000 times.

According to the fourth embodiment, as hereinabove described, the transfer gate electrode 7 is provided between the transfer gate electrode 8 and the readout gate electrode 10 and the multiplier gate electrode 9 is provided on the side opposite to the transfer gate electrode 7 and the readout gate electrode 10 with respect to the transfer gate electrode 8, whereby electrons can be transferred to the floating diffusion region 5 by changing a relatively low voltage (about 2.9 V) applied to the transfer gate electrode 7 when the CMOS image sensor reads data without transferring the electrons to the floating diffusion region 5 by changing a high voltage (about 24 V) applied to the multiplier gate electrode 9 for forming an electric field impact-ionizing the electrons. When the CMOS image sensor reads data, therefore, the potential of a portion of the transfer channel 3 located under the readout gate electrode 10 can be prevented from fluctuation resulting from change of a high potential (about 25 V) in the portion (electron multiplying portion 3b) of the transfer channel 3 located under the multiplier gate electrode 9, and hence the number of the electrons transferred to the floating diffusion region 5 can be more effectively prevented from dispersion. Consequently, the CMOS image sensor can correctly read data.

Although the present invention has been described and illustrated in detail, it is clearly understood that the same is by way of illustration and example only and is not to be taken by way of limitation, the spirit and scope of the present invention being limited only by the terms of the appended claims.

For example, while each of the aforementioned first to fourth embodiments is applied to the active CMOS image sensor amplifying a charge signal in each pixel as an exemplary CMOS image sensor, the present invention is not restricted to this but is also applicable to a passive CMOS image sensor not amplifying a charge signal in each pixel.

While the portions of the transfer channel located under the transfer gate electrodes and the readout gate electrode respectively are controlled to the potentials of about 4 V when the transfer gate electrodes and the readout gate electrode are in the ON states in each of the aforementioned first to fourth embodiments, the present invention is not restricted to this but the portions of the transfer channel located under the transfer gate electrodes and the readout gate electrode respectively may alternatively be controlled to different potentials when the transfer gate electrodes and the readout gate electrode are in the ON states.

While the n-type transfer channel, the n-type photodiode portion and the n-type floating diffusion region are formed on the surface of the p-type silicon substrate in each of the aforementioned first to fourth embodiments, the present invention is not restricted to this but a p-type well region may alternatively be formed on the surface of the n-type silicon substrate, for forming the n-type transfer channel, the n-type photodiode portion and the n-type floating diffusion region on a surface of the p-type well region.

While the electrons are employed as the signal charges in each of the aforementioned first to fourth embodiments, the present invention is not restricted to this but holes may alternatively be employed as the signal charges by entirely reversing the conductivity type of the substrate impurity and the polarities of the applied voltages.

While the gate electrodes are provided so as not to overlap with the photodiode portion in plan view in each of the aforementioned first to fourth embodiments, the present invention is not restricted to this but a part of the gate electrode may be partially overlap with the photodiode portion in plan view.

What is claimed is:

1. An image sensor comprising:
a first electrode for forming an electric field storing signal charges;
a second electrode for forming another electric field increasing the number of the signal charges;
a photoelectric conversion portion generating the signal charges;
a voltage conversion portion for converting the signal charges to a voltage;
a third electrode for transferring the signal charges to said voltage conversion portion;
a fourth electrode provided between said first electrode and said second electrode for transferring the signal charges; and
a transfer channel provided under said first electrode, said second electrode, said third electrode and said fourth electrode for performing a signal charge transferring operation and a signal charge increasing operation, wherein
said first electrode, said second electrode, said third electrode and said fourth electrode are formed between said photoelectric conversion portion and said voltage conversion portion and provided so as not to overlap with at least a part of said photoelectric conversion portion in plan view.

2. The image sensor according to claim 1, wherein
said first electrode, said second electrode, said third electrode and said fourth electrode are provided so as not to overlap with said photoelectric conversion portion in plan view.

3. The image sensor according to claim 1, wherein
an insulating film is formed on a surface of said transfer channel and said insulating film is provided so as not to overlap with said photoelectric conversion portion in plan view.

4. The image sensor according to claim 1, wherein
said first electrode is provided to be adjacent to said photoelectric conversion portion, and said second electrode is provided to be adjacent to a side of said fourth electrode provided between said first electrode and said second electrode, opposite to said photoelectric conversion portion.

5. The image sensor according to claim 4, wherein
said first electrode, said second electrode, said third electrode and said fourth electrode extend in a direction intersecting with a signal charge transfer direction and are formed at the prescribed intervals, and
said photoelectric conversion portion is formed on a side of said first electrode opposite to a side on which said voltage conversion portion is formed, in plan view.

6. The image sensor according to claim 1, wherein
said second electrode is provided to be adjacent to said photoelectric conversion portion, and said first electrode is provided to be adjacent to a side of said fourth electrode provided between said first electrode and said second electrode, opposite to said photoelectric conversion portion.

7. The image sensor according to claim 6, wherein
said first electrode, said second electrode, said third electrode and said fourth electrode extend in a direction intersecting with a signal charge transfer direction and are formed at the prescribed intervals, and
said photoelectric conversion portion is formed on a side of said second electrode opposite to a side on which said voltage conversion portion is formed, in plan view.

8. The image sensor according to claim 1, wherein
said signal charge increasing operation of controlling said first electrode and said fourth electrode to transfer the signal charges stored in a portion of said transfer channel corresponding to said first electrode to a portion of said transfer channel corresponding to said second electrode in a state where said second electrode forms the electric field impact-ionizing the signal charges and said signal charge transferring operation of controlling said first electrode, said second electrode and said fourth electrode to transfer the signal charges increased in number by the electric field formed by said second electrode to said portion of said transfer channel corresponding to said first electrode are alternately performed.

9. The image sensor according to claim 8, wherein
a potential of a portion of said transfer channel corresponding to said third electrode is controlled to be lower than a potential of a portion of said transfer channel corresponding to said fourth electrode in said signal charge increasing operation of transferring the signal charges stored in said portion of said transfer channel corresponding to said first electrode to said portion of said transfer channel corresponding to said second electrode in the state where said second electrode forms the electric field impact-ionizing the signal charges and said signal charge transferring operation of transferring the signal charges increased in number by the electric field formed by said second electrode to said portion of said transfer channel corresponding to said first electrode.

10. The image sensor according to claim 1, wherein
a length of said third electrode in a direction along a signal charge transfer direction is larger than a length of each of any electrodes other than said third electrode in the direction along the signal charge transfer direction.

11. The image sensor according to claim 1, wherein
an impurity region having a conductivity type different from that of said photoelectric conversion portion is formed on a surface of said photoelectric conversion portion, and said first electrode, said second electrode, said third electrode and said fourth electrode are provided so as not to overlap with at least a part of said impurity region in plan view.

12. The image sensor according to claim 11, wherein
said first electrode, said second electrode, said third electrode and said fourth electrode are provided so as not to overlap with said impurity region in plan view.

13. The image sensor according to claim 1, wherein
an increasing portion of the signal charges is formed on a portion of said transfer channel corresponding to said second electrode by forming the electric field impact-ionizing the signal charges by said second electrode.

14. The image sensor according to claim 1, wherein
at least said photoelectric conversion portion, said voltage conversion portion, said first electrode, said second electrode, said third electrode and said fourth electrode are included in one pixel.

15. The image sensor according to claim 1, further comprising a reset gate line extending in a signal charge transfer direction and applying a signal for resetting the signal charges stored in said voltage conversion portion, wherein
said reset gate line is provided so as not to overlap with said photoelectric conversion portion in plan view.

16. The image sensor according to claim 1, wherein
said photoelectric conversion portion is provided on a region enclosed with said reset gate line and said first electrode or said second electrode in plan view.

17. A CMOS image sensor comprising:
a first electrode for forming an electric field storing signal charges;
a second electrode for forming another electric field increasing the number of the signal charges;
a photoelectric conversion portion generating the signal charges;
a voltage conversion portion for converting the signal charges to a voltage;
a third electrode for transferring the signal charges to said voltage conversion portion;
a fourth electrode provided between said first electrode and said second electrode for transferring the signal charges; and
a transfer channel provided under said first electrode, said second electrode, said third electrode and said fourth electrode for performing a signal charge transferring operation and a signal charge increasing operation, wherein
said first electrode, said second electrode, said third electrode and said fourth electrode are formed between said photoelectric conversion portion and said voltage conversion portion and provided so as not to overlap with at least a part of said photoelectric conversion portion in plan view, and
at least said photoelectric conversion portion, said voltage conversion portion, said first electrode, said second electrode, said third electrode and said fourth electrode are included in one pixel.

18. The CMOS image sensor according to claim 17, wherein
said first electrode, said second electrode, said third electrode and said fourth electrode are provided so as not to overlap with said photoelectric conversion portion in plan view.

19. The CMOS image sensor according to claim 17, wherein
said first electrode is provided to be adjacent to said photoelectric conversion portion, and said second electrode is provided to be adjacent to a side of said fourth electrode provided between said first electrode and said second electrode, opposite to said photoelectric conversion portion.
